(19) United States
(12) Patent Application Publication
(10) Pub. No.: US 2024/0006498 A1
(43) Pub. Date: Jan. 4, 2024

(54) FIELD EFFECT TRANSISTOR DEVICE

(71) Applicant: HUAWEI TECHNOLOGIES CO., LTD., Shenzhen (CN)

(72) Inventor: Samir MOUHOUBI, Nuremberg (DE)

(21) Appl. No.: 18/467,904

(22) Filed: Sep. 15, 2023

Related U.S. Application Data
(63) Continuation of application No. PCT/EP2021/056855, filed on Mar. 17, 2021.

(51) Int. Cl. H01L 29/423; H01L 29/20; H01L 29/45; H01L 29/47; H01L 29/778; H01L 29/40; H01L 29/66

(52) U.S. Cl. CPC H01L 29/42316; H01L 29/2003; H01L 29/452; H01L 29/475; H01L 29/7786; H01L 29/401; H01L 29/66462

(57) ABSTRACT

The present disclosure relates to a FET device (10), comprising a substrate (11), a GaN structure (15) covering a portion of the substrate (11), and a gate metal layer (17) on top of the GaN structure (15). The GaN structure (15) comprises at least one first section having a first height, and a second section having a second height that is smaller than the first height, wherein a first interface (41) between the at least one first section of the GaN structure (15) and the gate metal layer (17) has ohmic contact properties, and wherein a second interface (43) between the second section of the GaN structure (15) and the gate metal layer (17) has non-ohmic contact properties.

### CROSS-REFERENCE TO RELATED APPLICATIONS

This application is a continuation of International Application No. PCT/EP2021/056855, filed on Mar. 17, 2021, the disclosure of which is hereby incorporated by reference in its entirety.

### TECHNICAL FIELD

The present disclosure relates to a field effect transistor (FET) device and, in particular, to a high electron mobility transistor (HEMT) device. The present disclosure further relates to a method of fabricating such a FET device.

### BACKGROUND

Field effect transistors (FETs) are key components for many electronic devices. FETs, generally, comprise the three components: source, gate and drain. By applying a voltage to the gate, a current flow between the source and drain can be controlled.

High-electron-mobility transistors, so called HEMTs, are special types of FETs that have a channel that is formed by a heterojunction, i.e. a junction between two materials with different band gaps. There are different material combinations that can be used to form the heterojunction, such as AlGaAs/GaAs or AlGaN/GaN.

The HEMT market is dominated by two technology concepts: the ohmic gate concept and the Schottky gate concept. Thereby, the terms ohmic gate and Schottky gate refer to the interface between a gate structure and a metallic gate contact of the HEMT. Both concepts suffer from inherent limitations and technological issues. The main difference between the two concepts is the gate current, which is low in the case of a Schottky contact and high in the case of an ohmic contact. The choice of one of these concepts has a strong influence on the electrical characteristics of the HEMT, e.g. its voltage class, its resistance class or its reliability requirements, and, thus, limits the kind of devices that can be built with a certain HEMT.

FIG. 1 shows an example of a gallium nitride (GaN) HEMT structure according to a conventional example. This HEMT structure comprises an aluminum gallium nitride (AlGaN) layer on top of a substrate. A gallium nitride GaN layer is arranged on top of the AlGaN layer and is contacted by a gate metal layer. The GaN layer and the AlGaN layer form a specific part of the HEMT that can be modeled to either form an ohmic contact or a Schottky contact.

FIG. 2a shows an equivalent circuit diagram of the gate of the GaN HEMT from FIG. 1 with an ohmic contact. A HEMT with such an ohmic gate has the advantage that the voltage of the mid-node (Vm) is directly controlled by the applied gate voltage (Vg) and, thus, no floating region exists in the GaN layer. Furthermore, it is possible to evacuate carriers in both positive and negative biasing, allowing for a robust and stable gate with good dynamic and long term performance. However, the current that is needed to drive the gate can be large which causes a high current consumption in the full system, requiring complex driving design schemes.

FIG. 2b shows an equivalent circuit diagram of the gate of the GaN HEMT from FIG. 1 with a Schottky contact. A HEMT with such a Schottky gate has the advantage that the gate current can be reduced due to the possibility of reverse biasing the Schottky contact between the applied gate voltage (Vg) and the mid-node voltage (Vm). As a consequence, an easier driving mode can be chosen and the scalability, e.g., with regard to voltage class and resistance class, is enhanced. However, the mid-node voltage (Vm) is electrically floating, which might cause a poor dynamic performance. Further, the depletion at the Schottky contact can lead to a reduced gate reliability.

In summary, the ohmic gate is a robust and reliable concept for high voltage class devices but less suitable for low voltage and/or low switch-on resistance (Ron) devices. The Schottky gate, on the other hand, is more suitable for low voltage and/or low Ron devices but has inherent weaknesses. It is difficult and costly to develop different types of HEMTs with these two technologies and properties in parallel. Thus, there is a need for improved FET devices and, specifically, improved HEMT devices.

### SUMMARY

In view of the above-mentioned problems and disadvantages, the present disclosure aims to improve field effect transistor devices, in particular HEMT devices, and their fabrication methods. The present disclosure has thereby the object to provide for an improved field effect transistor device.

The object of the present disclosure is achieved by the embodiments provided in the enclosed independent claims. Advantageous implementations of the present disclosure are further defined in the dependent claims.

According to a first aspect, a field effect transistor (FET) device is provided, comprising: a substrate; a gallium nitride (GaN) structure covering a portion of the substrate; a gate metal layer on top of the GaN structure; wherein the GaN structure comprises: at least one first section having a first height, and a second section having a second height that is smaller than the first height; wherein a first interface between the at least one first section of the GaN structure and the gate metal layer has ohmic contact properties; and wherein a second interface between the second section of the GaN structure and the gate metal layer has non-ohmic contact properties.

This achieves the advantage that a FET device with a hybrid gate is formed, which has electrical properties that combine aspects of an ohmic gate and a non-ohmic gate, e.g. a Schottky gate. In particular, gate properties, such as the gate current level, can be controlled by the aspect ratio between the at least one first section of the GaN structure and the second section of the GaN structure, i.e. by the aspect ratio between interfaces with ohmic and non-ohmic contact properties.

The substrate may comprise a base structure with one or more layers on top. In particular, the substrate comprises an aluminum gallium nitride (AlGaN) top layer. The GaN structure can be arranged on top of the AlGaN layer. A channel can be formed below the AlGaN layer in a region under the GaN structure.

Further, source and drain structures of the FET device can be arranged on both ends of the GaN structure.

In an implementation form of the first aspect, the first interface forms an ohmic contact, and the second interface forms a Schottky junction or a p-n junction.

In particular, the ohmic contact of the first interface can also be formed by a tunneling junction or a quasi-ohmic contact between the GaN structure and the gate metal layer.

In an implementation form of the first aspect, the first interface makes up less than 10%, in particular less than 5%, more particular less than 1%, of a total interface area between the GaN structure and the gate metal layer, the total interface area comprising the first interface and the second interface. This achieves the advantage that the electrical properties of the gate, e.g. a gate current, can be adjusted efficiently.

For example, by reducing the portion of the ohmic interface on the total interface, a gate current of the FET device is reduced.

Alternatively, the first interface can make up more than 10% of the total interface area. In this way, the gate current of the FET device can be increased.

In an implementation form of the first aspect, the GaN structure comprises a plurality of first sections that are separated from each other.

In particular, the plurality of first sections can be distributed across the gate area.

In an implementation form of the first aspect, a separating layer is arranged around the first interface on the GaN structure to physically separate the first interface from the second interface.

In particular, the separating layer is arranged around the at least one first section of the GaN structure. More particular, a respective separating layer is arranged around each of the first sections of the GaN structure. The separating layer can be formed from an insulating material. For instance, the separating layer is a dielectric.

In an implementation form of the first aspect, the GaN structure comprises a sloped transition region from the first section to the second section.

Alternatively, the transition from the at least one first section to the second section of the GaN structure can be abrupt, i.e. a drop of the height of the GaN structure at a 90° angle.

In an implementation form of the first aspect, the GaN structure further comprises a third section having a third height that is different from the first and the second height. This achieves the advantage that the FET device can comprise a third interface that is formed between the third section and the gate metal layer. In particular, the electrical properties of this third interface can be ohmic or non-ohmic.

In an implementation form of the first aspect, the GaN structure comprises a p-doped GaN (pGaN) layer, wherein a concentration of p-dopants in the pGaN layer is higher in a region below the first interface than in a region below the second interface. This achieves the advantage that the electrical properties of the first and/or second interface can be adjusted.

In particular, the first section and the second section of the GaN structure are at least partially formed from the pGaN layer.

By increasing the doping in the region below the first interface, said first interface can be turned into an ohmic interface. The exact electrical properties of the first interface can be further adjusted via the concentration of dopants, e.g. magnesium, in the pGaN layer close to the interface.

In an implementation form of the first aspect, the GaN structure comprises an n-doped GaN (nGaN) layer that is arranged above of the pGaN layer, wherein the nGaN layer at least partially covers the pGaN layer.

In particular, by adding the nGaN layer, the electrical properties of the first and/or second interface can be further adjusted. For example, if the nGaN layer is arranged on top of the pGaN layer in the second section of the GaN structure, a Schottky junction formed by the second interface can be changed to a p-n junction. If the nGaN layer is arranged on top of the pGaN layer in the first section of the GaN structure, the first interface may form a tunnel junction, which has mostly ohmic contact properties.

The first section and the second section of the GaN structure can each comprise parts of the pGaN and of the nGaN layer.

In an implementation form of the first aspect, the nGaN layer is only arranged above the pGaN layer in the at least one first section of the GaN structure, or the nGaN layer is only arranged above the pGaN layer in the second section of the GaN structure. This achieves the advantage that only the electrical properties of one of the two interfaces is further adjusted by the nGaN layer, while the other interface is not affected.

In an implementation form of the first aspect, the nGaN layer is arranged above the pGaN layer in the first section and the second section of the GaN structure. This achieves the advantage that the electrical properties of both interfaces can be adjusted by the nGaN layer.

In an implementation form of the first aspect, the nGaN layer has a bigger thickness in the first section than in the second section of the GaN structure. This achieves the advantage that the electrical properties of both interfaces can be adjusted by the nGaN layer.

In an implementation form of the first aspect, the nGaN layer only covers a portion of the pGaN layer in the first section and/or the second section of the GaN structure. This achieves the advantage that a hybrid gate structure can be generated by only partially covering the pGaN layer in the first and/or second section with the nGaN layer.

In an implementation form of the first aspect, the concentration of n-dopants in the nGaN layer is higher in the first section than in the second section of the GaN structure. This achieves the advantage that the electrical properties of the first and/or second interface can be further adjusted.

In an implementation form the first aspect, the GaN structure further comprises an undoped GaN layer. For example, the undoped GaN layer can form a base layer of the GaN structure. The pGaN layer and/or the nGaN layer can be arranged on said base layer.

In an implementation form of the first aspect, the gate metal layer is formed by a metal stack, wherein the metal stack comprises any one of the following material combinations: Ni/Au, Ni/Ag, Pd/Au, Cr/Au, Pt/Au, Ti/Pt/Au, Ni/Si, W/Si, Ti/Al, Ti/Al/Ti, or TiN/Al/TiN.

In an implementation form of the first aspect, the FET device is a GaN-gate high electron mobility transistor (HEMT) device.

According to a second aspect, a method of fabricating an FET device is provided, comprising the steps of:
providing a substrate;
forming a GaN structure on top of the substrate, wherein the GaN structure comprises at least one first section having a first height, and a second section having a second height that is smaller than the first height;
forming a gate metal layer on top of the GaN structure;
wherein a first interface between the at least one first section of the GaN structure and the gate metal layer has ohmic contact properties, and wherein a second interface between the second section of the GaN structure and the gate metal layer has non-ohmic contact properties.

This achieves the advantage that a FET device with a hybrid gate is formed, which has electrical properties that combine aspects of an ohmic gate and a non-ohmic gate, e.g. a Schottky gate. In particular, gate properties, such as the gate current level, can be controlled by the aspect ratio between the at least one first section of the GaN structure and the second section of the GaN structure, i.e. by the aspect ratio between interfaces with ohmic and non-ohmic contact properties.

In an implementation form of the second aspect, the first interface forms an ohmic contact, and/or the second interface forms a Schottky junction or a p-n junction.

In an implementation form of the second aspect, the first interface makes up less than 10%, in particular less than 5%, more particular less than 1%, of a total interface area between the GaN structure and the gate metal layer, the total interface area comprising the first interface and the second interface.

In an implementation form of the second aspect, the GaN structure comprises a plurality of first sections that are separated from each other.

In an implementation form of the second aspect, a separating layer is arranged around the first interface on the GaN structure to physically separate the first interface from the second interface.

In an implementation form of the second aspect, the GaN structure comprises a sloped transition region from the first section to the second section.

In an implementation form of the second aspect, the GaN structure further comprises a third section having a third height that is different from the first and the second height.

In an implementation of the second aspect, the GaN structure comprises a pGaN layer; wherein a concentration of p-dopants in the pGaN layer is higher in a region below the first interface than in a region below the second interface.

In an implementation form of the second aspect, the GaN structure comprises a nGaN layer that is arranged above of the pGaN layer, wherein the nGaN layer at least partially covers the pGaN layer.

In an implementation form of the second aspect, the nGaN layer is only arranged above the pGaN layer in the at least one first section of the GaN structure, or the nGaN layer is only arranged above the pGaN layer in the second section of the GaN structure.

In an implementation form of the second aspect, the nGaN layer is arranged above the pGaN layer in the first section and the second section of the GaN structure.

In an implementation form of the second aspect, the nGaN layer has a bigger thickness in the first section than in the second section of the GaN structure.

In an implementation form of the second aspect, the nGaN layer only covers a portion of the pGaN layer in the first section and/or the second section of the GaN structure.

In an implementation form of the second aspect, a concentration of n-dopants in the nGaN layer is higher in the first section than in the second section of the GaN structure.

In an implementation form of the second aspect, the GaN structure further comprises an undoped GaN layer.

In an implementation form of the second aspect, the gate metal layer is formed by a metal stack, wherein the metal stack comprises any one of the following material combinations: Ni/Au, Ni/Ag, Pd/Au, Cr/Au, Pt/Au, Ti/Pt/Au, Ni/Si, W/Si, Ti/Al, Ti/Al/Ti, or TiN/Al/TiN.

In an implementation form of the second aspect, the FET device is a GaN-gate high electron mobility transistor, HEMT, device.

It has to be noted that all devices, elements, units and means described in the present application could be implemented in the software or hardware elements or any kind of combination thereof. All steps which are performed by the various entities described in the present application as well as the functionalities described to be performed by the various entities are intended to mean that the respective entity is adapted to or configured to perform the respective steps and functionalities. Even if, in the following description of specific embodiments, a specific functionality or step to be performed by external entities is not reflected in the description of a specific detailed element of that entity which performs that specific step or functionality, it should be clear for a skilled person that these methods and functionalities can be implemented in respective software or hardware elements, or any kind of combination thereof.

### BRIEF DESCRIPTION OF DRAWINGS

The above described aspects and implementation forms of the present disclosure will be explained in the following description of specific embodiments in relation to the enclosed drawings, in which:

FIG. 1 shows an example of a HEMT structure according to a conventional example;

FIGS. 2a-b show equivalent circuit diagrams of a gate of the HEMT structure from FIG. 1;

FIGS. 3a-e show schematic diagrams of an FET device according to different embodiments;

FIGS. 4a-b show a perspective view and a top view of an FET device according to an embodiment;

FIG. 5 shows an equivalent circuit diagram of an FET device according to an embodiment;

FIG. 6 shows a chart of the relationship between a gate current of an FET device and interface properties of the respective gate according to an embodiment;

FIGS. 7a-d show top views of a gate area of a FET device according to different embodiments; and

FIGS. 8a-c show steps of a method for fabricating a FET device according to an embodiment.

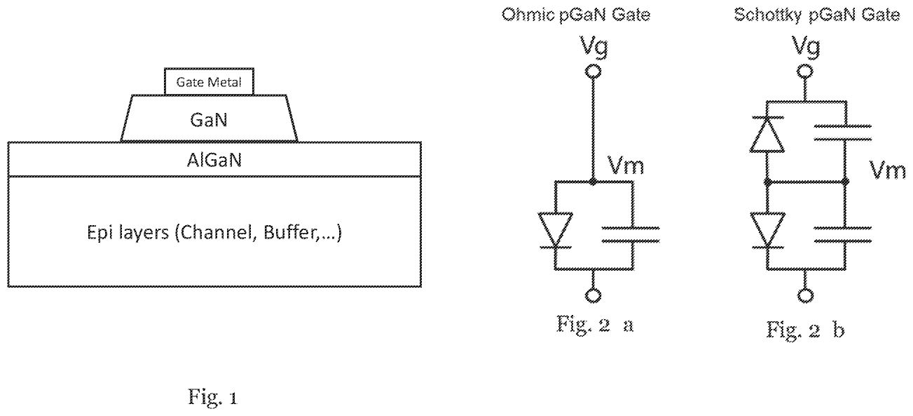

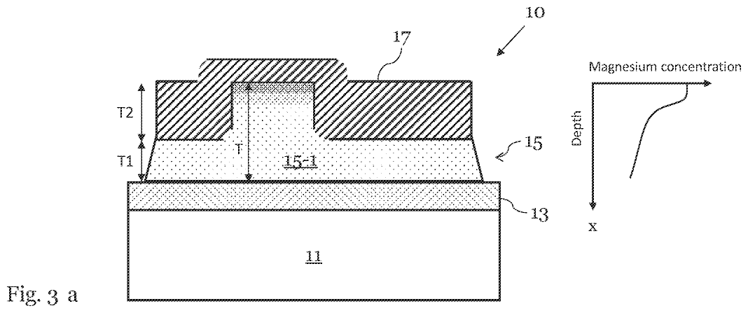

### DETAILED DESCRIPTION OF EMBODIMENTS

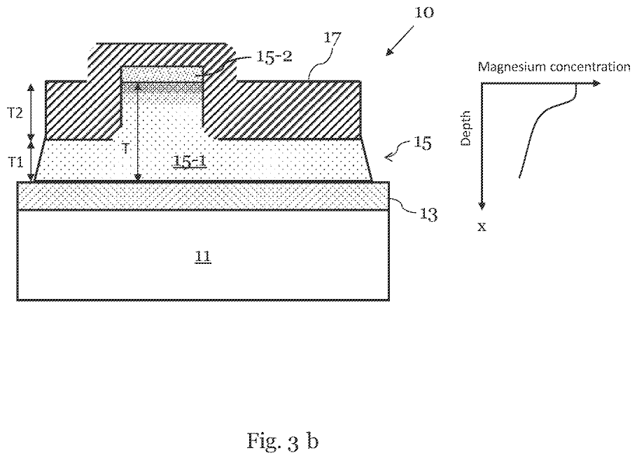

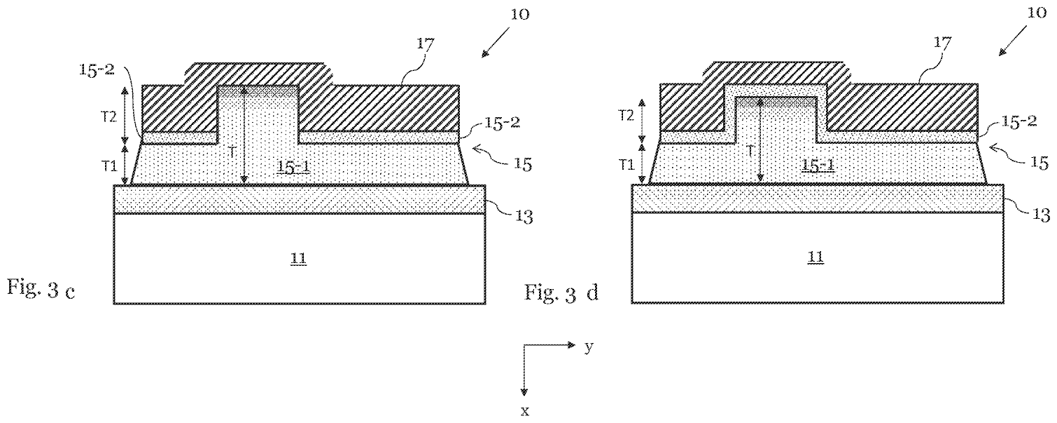

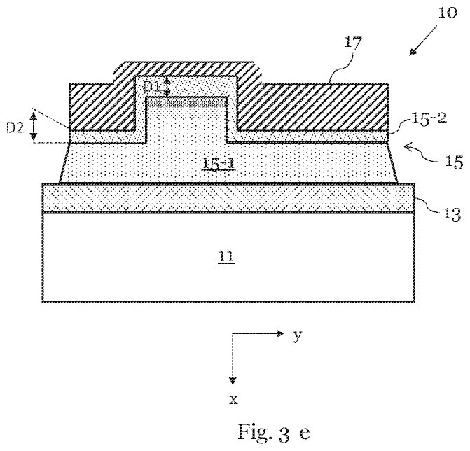

FIGS. 3a-e show schematic diagrams of an FET device 10 according to different embodiments.

The FET device 10, according to the embodiments shown in FIGS. 3a to 3e, comprises a substrate 11, a GaN structure 15 covering a portion of the substrate 11, and a gate metal layer 17 on top of the GaN structure 15. The GaN structure 15 comprises at least one first section having a first height, and a second section having a second height that is smaller than the first height, wherein a first interface between the at least one first section of the GaN structure 15 and the gate metal layer 17 has ohmic contact properties, and wherein a second interface between the second section of the GaN structure 15 and the gate metal layer has non-ohmic contact properties.

The substrate 11 may comprise a base structure with one or more layers on top. In particular, the substrate comprises an AlGaN top layer 13. The GaN structure 15 can be arranged on top of the AlGaN layer 13.

The substrate 11 can comprise a heteroepitaxial bulk material, e.g. GaN-on-SOI, GaN on sapphire, or GaN-on SiC. The substrate 11 can further comprise a GaN-on-GaN material. In particular, the substrate 11 comprises layers that where formed by an epitaxial growth process.

A channel of the FET device 10 can be formed below the AlGaN layer 13 in a region under the GaN structure 15, in particular in an interface between the AlGaN layer 13 and an underlying layer of the substrate 11.

Further, source and drain structures of the FET device 10 can be arranged on both ends of the GaN structure 15 (not shown in FIGS. 3a to 3e).

By employing two different interfaces within one gate, an FET device 10 with a hybrid gate is formed. Such an FET device 10 can have gate properties that combine aspects of an ohmic gate and a non-ohmic gate. For example, the first interface forms an ohmic contact, and the second interface forms a Schottky junction (i.e. Schottky barrier) or a p-n junction. The electrical properties of the gate, e.g. gate current, gate reliability or switch-on resistance (Ron), are a combination of the properties of the ohmic and the Schottky or p-n portion of the gate. By controlling the design parameters of these portions, in particular their aspect ratios and/or material compositions, the electrical properties of the gate of the FET device 10 can be adjusted. Hereby, ohmic contact may refer to any contact that behaves like an ohmic contact, i.e. a contact that exhibits the electrical properties of an ohmic contact.

In particular, the interface with ohmic contact properties exhibits a higher leakage current than the interface with the non-ohmic contact properties.

The GaN structure 15 can be formed on a planar surface, as shown in FIGS. 3a to 3e, or a filling layer, for example in case of a regrowth of the GaN structure 15 in a trench gate.

The GaN structure 15 can, further, comprise a p-doped GaN (pGaN) layer 15-1. In the embodiment shown in FIG. 3a, the GaN structure 15 is formed from this pGaN layer 15-1, whereas, in the embodiments shown in FIGS. 3b-e, the GaN structure 15 comprises the pGaN layer 15-1 with an additional n-doped GaN layer 15-2 on top. Via the p-doping of the pGaN layer 15-1, the interface properties between the first and second section of the GaN structure 15 and the gate metal layer 17 can be further adjusted. For example, by adjusting the doping concentration of the pGaN layer 15-1 a p-n junction at any one of the interfaces can be turned into an ohmic contact.

The doping of the pGaN layer 15-1 can be non-uniform. For example, a concentration of p-dopants, e.g. magnesium (Mg), in the pGaN layer 15-1 is enhanced at the top of the pGaN layer 15-1 in the first section of the GAN structure 15, close to the interface with the gate metal layer 17. Thus, the concentration of p-dopants in the pGaN layer 15-1 is higher in a region below the first interface than in a region below the second interface.

FIGS. 3a and 3b contain a chart that shows the doping concentration of the p-dopant (magnesium concentration) in the pGaN layer 15-1 as function of the distance from the first interface (depth). The doping concentration is highest directly at the first interface and drops to a lower level further from the gate metal layer 17. Further, in FIGS. 3a to 3e, the increased doping concentration close to the first interface is indicated by a darker shading of the pGaN layer 15-1.

For example, the first interface is an ohmic interface due to the high magnesium concentration in the pGaN layer 15-1 below the gate metal layer 17 in the first section, while the second interface is a Schottky interface due to the reduced magnesium concentration in the pGaN layer below the gate metal layer 17 in the second section.

As indicated in FIGS. 3a and 3b, the pGaN layer 15-1 in the first section of the GaN structure 15 has a first height T, which is, typically but not exclusive, between 50 nm and 1000 nm. The pGaN layer 15-1 in the second section of the GaN structure has a second height of T1<T, wherein T=T1+T2. The two thicknesses T1 and T2 can be optimized, such that the GaN layer 15-1 has a very high Mg doping level at the first interface (e.g., >5e19) and a mid to low doping level at the second interface (e.g., <5e19).

The pGaN layer can be formed from any p-type GaN irrespective of its doping element, e.g. magnesium (Mg), and its method of formation, e.g. metalorganic chemical vapor deposition (MOCVD) growth, molecular-beam epitaxy (MBE), delta doping or other deposition/doping techniques.

As shown in the examples depicted in FIGS. 3a to 3e, a transition from the at least one first section to the second section of the GaN structure can be abrupt, i.e. a drop of the height of the GaN structure at a 90° angle. Alternatively, the GaN structure 15 may comprise a sloped transition, e.g. in the form of a transition region, from the first to the second section.

The GaN structure 15 may further comprise a third section having a third height that is different from the first and the second height (not shown in FIGS. 3a to 3e). For example, the third section can have a third interface to the gate metal layer 17, which has either ohmic or non-ohmic contact properties.

The gate metal layer 17 can be formed from at least one metal stack. The metal stack is contacting the GaN structure 15 to form the first respectively second interface. For example, the metal stack comprises any one of the following material combinations: Ni/Au, Ni/Ag, Pd/Au, Cr/Au, Pt/Au, Ti/Pt/Au, Ni/Si, W/Si, Ti/Al, Ti/Al/Ti, or TiN/Al/TiN. However, other suitable material combinations are also possible.

In particular, the gate metal layer 17 can comprise different sections that are formed from different material, i.e. have a different material composition. For example, a first section of the gate metal layer 17 that is in contact with the first section of the GaN structure 15 is formed from a first metal stack, and a second section of the gate metal layer 17 that is in contact with the second section of the GaN structure 15 is formed from a second metal stack. Viewed in cross section across the x-y-plane, the edges of these metal stacks can be straight, sloped or V-shaped. The shape of the metal stacks can depend on the metal properties and on etching methods used to fabricate the FET device 10. The metal stacks can further be self-aligned or not self-aligned, e.g. extending over or retracted from each other or from the GaN structure 15.

Alternative to these metal stack(s), the gate metal layer 17 can also be formed from single materials, such as indium tin oxide (ITO) or a magnesium films/electrodes.

In the embodiments shown in FIGS. 3b to 3e, the GaN structure 15 comprises an additional n-doped GaN (nGaN) layer 15-2 that is arranged above the pGaN layer 15-1 of the GaN structure 15.

The nGaN layer 15-2 can also be arranged to only cover a portion of the pGaN layer 15-1 in the first section and/or the second section of the GaN structure 15. In this way, a hybrid gate structure can be generated.

The nGaN layer 15-2 can be formed from any n-type GaN irrespective of its doping element, e.g. silicon (Si), and its method of formation, e.g. MOCVD growth, MBE, implantation, or deposition of a silicon rich layer and diffusion. The thickness of the n-type GaN layer 15-2 can be as small as 1 nm to 10 nm or larger than 10 nm (depending on the technological constraints). In particular, by means of the nGaN layer 15-2, the electrical properties of the first and/or second interface can be further adjusted.

In the embodiment shown in FIG. 3b, the nGaN layer 15-2 is arranged on the pGaN 15-1 in the first section of the GaN structure 15, i.e. on the pGaN layer 15-1 with thickness T.

In particular, the incorporation of this n-GaN layer 15-1 in the first section allows forming a tunneling junction in the first interface with ohmic contact properties. Thereby, the doping level of the n-type GaN at the interface with the p-type GaN is high enough to squeeze the band diagram and cause carrier tunneling.

In the embodiment shown in FIG. 3c, the nGaN layer 15-2 is arranged on the pGaN layer 15-1 in the second section of the GaN structure 15, i.e. on the pGaN layer 15-1 with thickness Ti.

In particular, the insertion of the n-type GaN layer 15-2 on top of the pGaN layer 15-1 in the first section allows to turn the second interface from a Schottky junction to a p-n junction. This may result in an improvement of the gate breakdown voltage, in particular a larger gate overdrive, and a better gate reliability. In addition, the problem of high dependence to the interface quality and metal work function can be mitigated.

In the embodiment shown in FIG. 3d, the nGaN layer 15-2 is arranged on the pGaN layer 15-1 in both the first and the second section of the GaN structure 15. For example, the nGaN layer 15-2 can have the same height in both sections.

In particular, the insertion of the nGaN layer 15-2 in the first and second section of the GaN structure 15 allows adjusting the gate leakage of both interfaces between the GaN structure 15 and the gate metal layer 17. For example, the first interface has a higher leakage due to the higher p-type doping in the pGaN layer 15-1 and the second interface has a lower leakage.

In the embodiment shown in FIG. 3e, the nGaN layer 15-2 is arranged on the pGaN 15-1 in the first and second section of the GaN structure 15. Thereby, the nGaN layer in the first section has a different thickness and/or a different doping level than the nGaN layer 15-2 in the second section.

For example, the nGaN layer 15-2 has a height of D1 in the first section and a height of D2 in the second section, wherein D1>D2.

Further, the nGaN layer 15-2 in the first section can be heavily doped with n-dopants to allow tunneling between the pGaN layer 15-1 and the gate metal layer 17, and the nGaN layer 15-2 in the second section can have a lower doping concentration to allow the formation of a p-n junction at the second interface (to replace the conventional Schottky junction).

Such nGaN layers 15-2 with varying doping concentrations and/or thicknesses D1 and D2 are, for example, fabricated by MOCVD growth in combination with etching and patterned regrowth, by MBE, by implantation, or by deposition of a silicon rich layer and diffusion.

The nGaN layer(s) 15-2 can be optimized, e.g. via their thickness or doping level, to fulfill target specifications. For example, the n-type doping can be high enough to enhance band bending and create a tunneling junction. The nGaN layer 15-2 can also be used to convert a Schottky junction to a pn-junction.

In addition to the pGaN layer 15-1 and the nGaN layer 15-2, the GaN structure of the FET device 10 can further comprise an undoped GaN layer. This undoped GaN layer can form a base layer of the GaN structure 15. The GaN structure 15 can further comprise multiple pGaN layers 15-1 and/or nGaN layers 15-2. In particular, the GaN structure 15 is formed from a stack of multiple GaN layers.

In the examples shown in FIGS. 3a to 3e, FET devices 10 with GaN structures 15 having a single first section surrounded by a second section are shown. However, the FET device 10 can also comprise a plurality of first sections, each first section having a first height that is larger than the second height of the second section.

FET devices 10, as shown in FIGS. 3a to 3e, can be used in power semiconductor devices, and, specifically, in GaN high electron mobility transistor (HEMT) devices. In particular, the FET device 10 forms a pGaN-gate HEMT, i.e. a GaN HEMT with a gate formed from a pGaN semiconductor to obtain E-Mode (enhanced mode) functionality. Such HEMT devices can be deployed in various different technology fields, such as power supply, automotive, LiDAR, servers, adaptors or DC/DC converters.

In particular, the FET device 10 can form a generic HEMT structure that further comprises a back barrier, multiple conducting channels, multiple barrier thicknesses, recessed AlGaN or recessed pGaN.

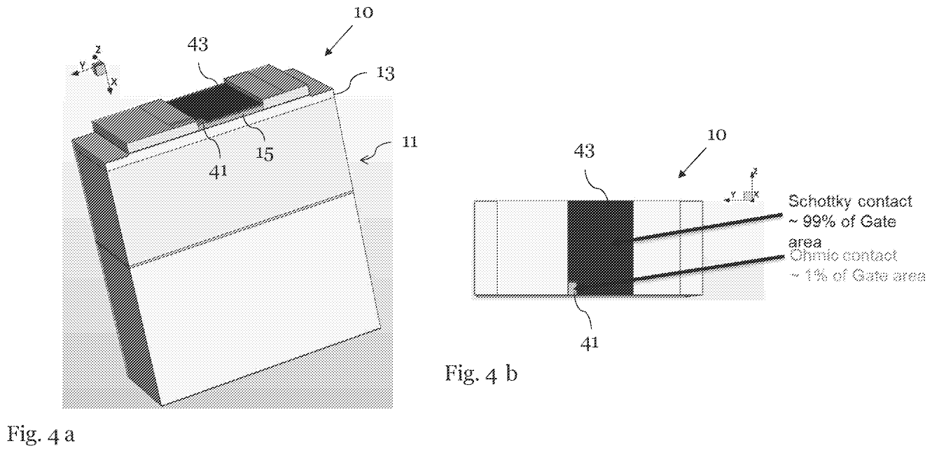

FIGS. 4a-b show a perspective view and a top view of the FET device 10 according to an embodiment.

In the example shown in FIGS. 4a-b, the gate area is divided into two interfaces, wherein the first interface 41 has ohmic contact properties (ohmic interface 41) and the second interface 43 has Schottky contact properties (Schottky interface 43). Thereby, the first interface 41 is the interface between the first section of the GAN structure 15 and the gate metal layer 17 and the second interface 43 is the interface between the second section of the GAN structure 15 and the gate metal layer 17. For the sake of simplicity, the gate metal layer 17 is not shown in FIGS. 4a-b.

In the example shown in FIGS. 4a and 4b, the FET device 10 has a hybrid gate with ˜1% of the total gate area being defined as an ohmic contact and the rest as a Schottky contact. The simplified equivalent circuit of such a hybrid gate is depicted in FIG. 5.

The aspect ratio between the first interface 41 and the second interface 43 is adjustable via the aspect ratio of the first and second section of the GaN structure 15. In this way, the electrical properties of the gate, in particular the gate current, of the FET device 10 can be adjusted. Here, the aspect ratio between the first and second interface may refer to the size of the first interface to the size of the second interface, wherein the total gate interface of the FET device 10 is made up by the first and the second interface.

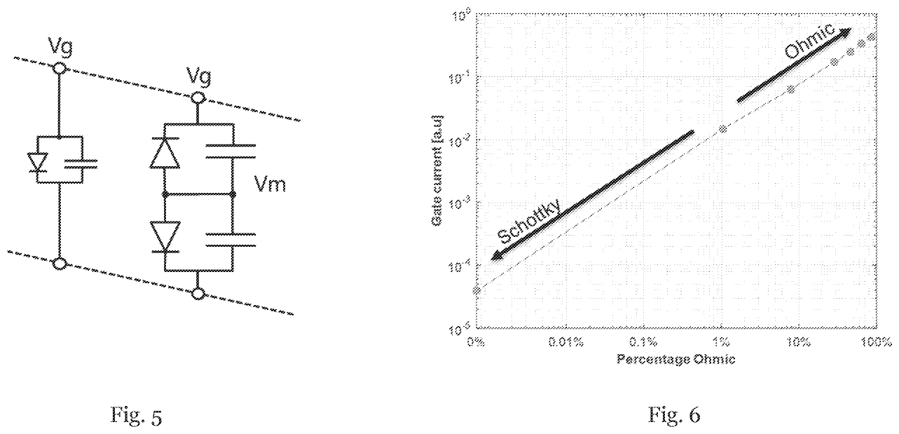

FIG. 6 shows a chart of the relationship between a gate current of the FET device and the interface properties, in particular the aspect ratio between the ohmic interface 41 and the Schottky interface 43, of the respective gate according to an embodiment.

As shown in FIG. 6, adjusting the aspect ratio between the ohmic and Schottky interfaces 41, 43 allows modulating the gate current of the FET device 10. In this way, the gate current level can be controlled by the aspect ratio between two different gate areas.

In particular, reducing the interface area of the ohmic interface 41 (and, thus, increasing the interface area of the Schottky interface 43) leads to a reduction of the gate current, while increasing the interface area of the ohmic interface 41 (and, thus, reducing the interface area of the Schottky interface 43) leads to an increase of the gate current. Therefore, to generate an FET device with a low gate current, the ohmic interface 41, can be designed to make up less than 10%, in particular less than 5%, more particular less than 1% of the total interface area of the gate.

By adjusting the aspect ratios between the ohmic and the Schottky interfaces 41, 43 of the gate, a hybrid (or distributed) gate is formed that can combine the benefits and, at the same time, mitigate the drawbacks of a fully ohmic or a fully Schottky gate. In this way, high voltage (HV) and low voltage (LV) GaN technology platforms can be combined into a single device with the possibility to adjust the specifications of the device by optimizing its layout to fit the needs of a specific product. Hence, resources and time spent to develop multiple technology platforms, e.g. Schottky gate and ohmic gate HEMT devices, can be reduced.

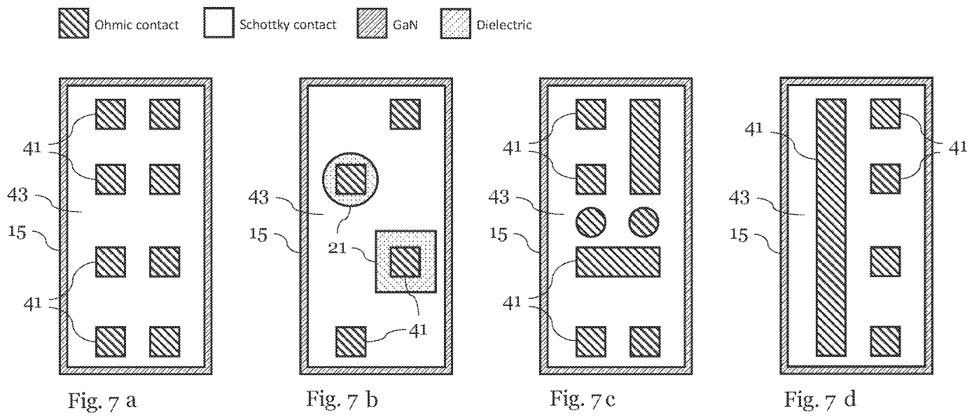

FIGS. 7a-d show top views of a gate area of the FET device 10 according to different embodiments. In particular, FIGS. 7a-d show the interfaces between the GaN structure and the gate metal layer 17 of the FET structure 10. Thereby, the gate metal layer 17 is omitted for the sake of simplicity. The embodiments shown in FIGS. 7a-d represent several possibilities for hybrid, i.e. distributed, ohmic-Schottky gate layouts.

As shown in FIGS. 7a-d, a major gate area can be defined as a Schottky interface 43. Depending on the target aspect ratio, several smaller areas of the gate can be defined as ohmic interfaces 41, or vice versa. In particular, whether a certain gate area forms an ohmic or Schottky interface with the gate metal layer 17 depends on the height of the GaN structure and/or the doping of the pGaN layer 15-1 of the GaN structure 15 at this area.

The ohmic interfaces 41 can be distributed across the gate area. The distributed ohmic interfaces 41 can have different shapes, e.g. square, rectangular, circular, or oval, and different sizes.

Further, the ohmic and Schottky interfaces 41, 43 can be physically separated by a separating layer 21, e.g. a dielectric, as shown in FIG. 7b. This separating layer 21 can be arranged on the GaN structure around each or some of the at least one first sections. Alternatively, the separating layer 21 can be arranged in the gate metal layer 17 and separate the gate metal layer 17 into a first contact area for contacting the first section of the GaN structure 15 and a second contact area for contacting the second section of the GaN structure 15.

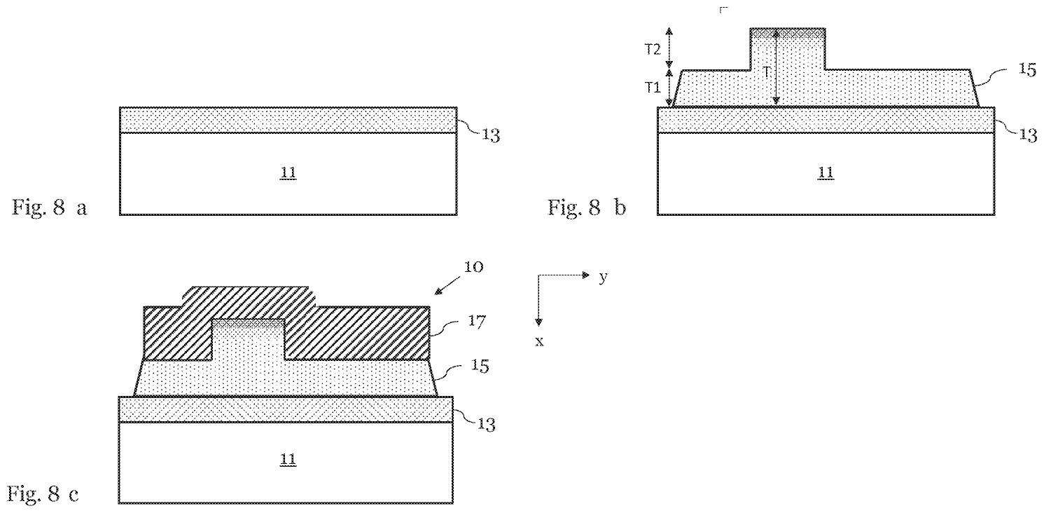

FIGS. 8a-d show steps of a method for fabricating the FET device 10 according to an embodiment.

In a first step, shown in FIG. 8a, the substrate 11 is provided. The substrate 11 may comprise a base structure with one or more layers on top, e.g. an AlGaN top layer 13.

In particular, the substrate 11 comprises a heteroepitaxial bulk material, e.g. GaN-on-SOI, GaN on sapphire, or GaN-on SiC. The substrate 11 can further comprise a GaN-on-GaN material. In particular, the substrate 11 comprises layers that where formed by an epitaxial growth process.

In a second step, shown in FIG. 8b, the GaN structure 15 is formed on top of the substrate 11, wherein the GaN structure 15 comprises the at least one first section having the first height T, and the second section having the second height T1 that is smaller than the first height T.

In particular, the GaN structure comprises or is formed from a pGaN layer 15-1. A doping concentration of the pGaN layer 15-1 can be enhanced at the top of the first section of the GaN structure 15.

The pGaN layer can be formed in two different ways: (i) a full pGaN layer 15-1 with thickness T is deposited and, subsequently, the pGaN layer 15-1 is recessed to a thickness of T1 in the area of the GaN structure 15 that forms the second section, wherein T1<T; or (ii) a full pGaN layer 15-1 with thickness T1 is deposited and, subsequently, a patterned regrowth process is used to generate a highly doped layer with thickness T2 on top of the layer with thickness T1 in the areas of the GaN structure 15 that form the at least one first section.

Optionally, a structured nGaN layer 15-2 can formed on top of the pGaN layer in the first and/or second section of the GaN structure 15 (not shown in FIGS. 8a-c).

The pGaN layer 15-1 and/or the nGaN layer 15-2 can be formed by a suitable fabrication process, such as MOCVD growth, MBE, implantation, delta doping and/or deposition of a silicon rich layer and diffusion.

In a third step, shown in FIG. 8c, the gate metal layer 17 on top of the GaN structure 15 is formed, wherein the first interface between the at least one first section (with height T) of the GaN structure 15 and the gate metal layer 17 has ohmic contact properties, and wherein the second interface between the second section (with height T1) of the GaN structure and the gate metal layer 17 has non-ohmic contact properties.

For example, the gate metal layer 17 can be formed by at least one metal stack. The metal stack can comprise any one of the following material combinations: Ni/Au, Ni/Ag, Pd/Au, Cr/Au, Pt/Au, Ti/Pt/Au, Ni/Si, W/Si, Ti/Al, Ti/Al/Ti, or TiN/Al/TiN.

The design of the various layers and structures in FIGS. 8a-c is just an example. The same principal method can be used to fabricating the FET device 10 with any one of the designs shown in FIGS. 3a-e and FIGS. 4a-b.

The present disclosure has been described in conjunction with various embodiments as examples as well as implementations. However, other variations can be understood and effected by those persons skilled in the art and practicing the claimed disclosure, from the studies of the drawings, this disclosure and the independent claims. In the claims as well as in the description the word “comprising” does not exclude other elements or steps and the indefinite article “a” or “an” does not exclude a plurality. A single element or other unit may fulfill the functions of several entities or items recited in the claims. The mere fact that certain measures are recited in the mutual different dependent claims does not indicate that a combination of these measures cannot be used in an advantageous implementation.

1. A field effect transistor, FET, device (10), comprising:
a substrate (11);
a gallium nitride, GaN, structure (15) covering a portion of the substrate (11);
a gate metal layer (17) on top of the GaN structure (15);
wherein the GaN structure (15) comprises:
at least one first section having a first height, and
a second section having a second height that is smaller than the first height;
wherein a first interface (41) between the at least one first section of the GaN structure (15) and the gate metal layer (17) has ohmic contact properties; and
wherein a second interface (43) between the second section of the GaN structure (15) and the gate metal layer (17) has non-ohmic contact properties.

2. The FET device (10) of claim 1,
wherein the first interface (41) forms an ohmic contact, and/or
wherein the second interface (43) forms a Schottky junction or a p-n junction.

3. The FET device (10) of claim 1,
wherein the first interface (41) makes up less than 10%, in particular less than 5%, more particular less than 1%, of a total interface area between the GaN structure (15) and the gate metal layer (17), the total interface area comprising the first interface (41) and the second interface (43).

4. The FET device (10) of claim 1,
wherein the GaN structure (15) comprises a plurality of first sections that are separated from each other.

5. The FET device (10) of claim 1,
wherein a separating layer (21) is arranged around the first interface (41) on the GaN structure (15) to physically separate the first interface (41) from the second interface (43).

6. The FET device (10) of claim 1,
wherein the GaN structure (15) comprises a sloped transition region from the first section to the second section.

7. The FET device (10) of claim 1,
wherein the GaN structure (15) further comprises a third section having a third height that is different from the first and the second height.

8. The FET device (10) of claim 1,
wherein the GaN structure (15) comprises a p-doped GaN, pGaN, layer (15-1), and
wherein a concentration of p-dopants in the pGaN layer (15-1) is higher in a region below the first interface (41) than in a region below the second interface (43).

9. The FET device (10) of claim 8,
wherein the GaN structure (15) comprises an n-doped GaN, nGaN, layer (15-2) that is arranged above of the pGaN layer (15-1), wherein the nGaN layer (15-2) at least partially covers the pGaN layer (15-1).

10. The FET device (10) of claim 9,
wherein the nGaN layer (15-2) is only arranged above the pGaN layer (15-1) in the at least one first section of the GaN structure (15), or
wherein the nGaN layer (15-2) is only arranged above the pGaN layer (15-1) in the second section of the GaN structure (15).

11. The FET device (10) of claim 9,
wherein the nGaN layer (15-2) is arranged above the pGaN layer (15-1) in the first section and the second section of the GaN structure (15).

12. The FET device (10) of claim 11,
wherein the nGaN layer (15-2) has a bigger thickness in the first section than in the second section of the GaN structure (15).

13. The FET device (10) of claim 10,
wherein the nGaN layer (15-2) only covers a portion of the pGaN layer (15-1) in the first section and/or the second section of the GaN structure (15).

14. The FET device (10) of claim 10,
wherein a concentration of n-dopants in the nGaN layer (15-2) is higher in the first section than in the second section of the GaN structure (15).

15. The FET device (10) of claim 8,
wherein the GaN structure (15) further comprises an undoped GaN layer.

16. The FET device (10) of claim 1,
wherein the gate metal layer (17) is formed by a metal stack, wherein the metal stack comprises any one of the following material combinations: Ni/Au, Ni/Ag, Pd/Au, Cr/Au, Pt/Au, Ti/Pt/Au, Ni/Si, W/Si, Ti/Al, Ti/Al/Ti, or TiN/Al/TiN.

17. The FET device (10) of claim 1,
wherein the FET device (10) is a GaN-gate high electron mobility transistor, HEMT, device.

18. Method of fabricating a field effect transistor, FET, device (10), comprising the steps of:
providing a substrate (11);
forming a gallium nitride, GaN, structure on top of the substrate (11), wherein the GaN structure (15) comprises at least one first section having a first height, and a second section having a second height that is smaller than the first height;
forming a gate metal layer (17) on top of the GaN structure (15);
wherein a first interface (41) between the at least one first section of the GaN structure (15) and the gate metal layer (17) has ohmic contact properties, and
wherein a second interface (43) between the second section of the GaN structure (15) and the gate metal layer (17) has non-ohmic contact properties.

19. The method of claim 18,
wherein the GaN structure (15) comprises a p-doped GaN, pGaN, layer; and
wherein a concentration of p-dopants in the pGaN layer (15-1) is higher in a region below the first interface (41) than in a region below the second interface (43).
